(19) United States
(12) Patent Application Publication
(10) Pub. No.: US 2026/0186031 A1
(43) Pub. Date: Jul. 2, 2026

(54) DIRECT CURRENT ESTIMATION DEVICE, POWER CONVERSION DEVICE, AND DIRECT CURRENT ESTIMATION METHOD

(71) Applicant: Hitachi Astemo, Ltd., Hitachinaka-shi, Ibaraki (JP)

(72) Inventor: Takashi NAKAZAWA, Hitachinaka-shi (JP)

(73) Assignee: Hitachi Astemo, Ltd., Hitachinaka-shi, Ibaraki (JP)

(21) Appl. No.: 18/728,150

(22) PCT Filed: Jan. 17, 2022
(86) PCT No.: PCT/JP2022/001449

§ 371 Date: Jul. 11, 2024

(51) Int. Cl. G01R 19/18; H02P 23/12; H02P 23/14

(52) U.S. Cl. CPC G01R 19/18; H02P 23/12; H02P 23/14

(57) ABSTRACT

A direct current estimation device that estimates a value of a direct current in a power conversion device that converts a direct current into an alternating current and outputs the alternating current to a dynamo-electric machine includes a Kalman filter that estimates a direct current estimation value, and the direct current estimation device uses at least an observation value of the alternating current and an angular velocity observation value of the dynamo-electric machine as input signals to the Kalman filter.

### TECHNICAL FIELD

The present invention relates to a direct current estimation device, a power conversion device, and a direct current estimation method.

### BACKGROUND ART

In the field of a control technique for converting a direct current into an alternating current, a direct current estimation method is being improved every day. Known examples are a current estimation device as described in PTL 1 and a method for estimating a high-voltage direct current by using an alternating current and an inverter pulse width modulation (PWM) signal.

### CITATION LIST

### Patent Literature

PTL 1: JP 2016-116311 A

### SUMMARY OF INVENTION

### Technical Problem

Incidentally, generally known direct current estimation using an alternating current and an inverter switching cycle signal has a problem of deterioration in efficiency of conversion from a direct current to an alternating current in a weak field region.

### Solution to Problem

A direct current estimation device according to an aspect of the present invention is a direct current estimation device that estimates a value of a direct current in a power conversion device that converts the direct current into an alternating current and outputs the alternating current to a dynamo-electric machine, the direct current estimation device including a Kalman filter that estimates a direct current estimation value, in which the direct current estimation device uses at least an observation value of the alternating current and an angular velocity observation value of the dynamo-electric machine as input signals to the Kalman filter.

### Advantageous Effects of Invention

According to the present invention, estimation accuracy of direct current estimation can be improved.

### BRIEF DESCRIPTION OF DRAWINGS

FIG. 1 is a diagram illustrating a schematic configuration of a motor drive device including a direct current estimation device according to one embodiment of the present invention.

FIG. 2 is a block diagram illustrating a detailed configuration of the direct current estimation device.

FIG. 3 is an operation flowchart of a Kalman filter system.

### DESCRIPTION OF EMBODIMENT

Hereinafter, an embodiment of the present invention will be described with reference to the drawings. The following description and drawings are examples for describing the present invention, and are omitted and simplified as appropriate for the sake of clarity of description. Further, in the following description, the same or similar elements and processing are denoted by the same reference signs, and redundant description may be omitted. Note that the contents described below are merely an example of the embodiment of the present invention, and the present invention is not limited to the following embodiment, and can be implemented in other various forms.

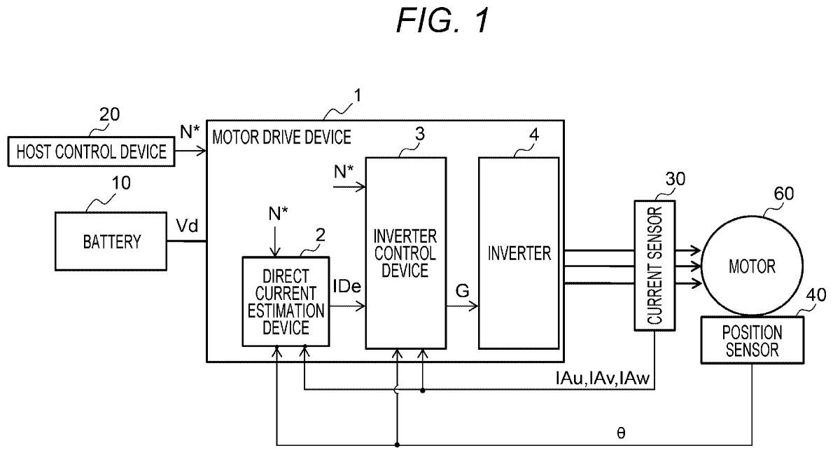

FIG. 1 is a diagram illustrating a schematic configuration of a motor drive device including a direct current estimation device according to one embodiment of the present invention. The motor drive device 1 is a device that rotationally drives a motor 60 using electric power supplied from a battery 10. The motor drive device 1 includes a direct current estimation device 2, an inverter control device 3, and an inverter 4. A torque command value N* is input from a host control device 20 to the motor drive device 1.

The battery 10 supplies direct current power of a voltage Vd to the motor drive device 1. The motor drive device 1 functions as a power conversion device that converts the direct current power supplied from the battery 10 into three-phase alternating current power and outputs the three-phase alternating current power to the motor 60. A current sensor 30 detects alternating current values (hereinafter, referred to as alternating current observation values IAu, IAv, and IAw) of corresponding phases of the three-phase alternating current power output from the motor drive device 1, and inputs the alternating current observation values IAu, IAv, and IAw to the motor drive device 1. A position sensor 40 detects a rotation angle indicating a rotation position of a rotor of the motor 60, and outputs a detected rotation angle observation value θ to the motor drive device 1.

The direct current estimation device 2 estimates a value (hereinafter, referred to as a direct current estimation value IDe) of the direct current flowing from the battery 10 to the inverter 4, based on the torque command value N* input to the motor drive device 1, the alternating current observation values IAu, IAv, and IAw detected by the current sensor 30, and the rotation angle observation value θ detected by the position sensor 40. The estimated direct current estimation value IDe is input to the inverter control device 3.

The inverter control device 3 calculates a current command value for bringing an output torque from the motor 60 close to the torque command value N*, based on the direct current estimation value IDe estimated by the direct current estimation device 2, the battery voltage Vd of the battery 10, and the rotation angle observation value θ detected by the position sensor 40, and generates a gate signal G in accordance with the calculated current command value. The gate signal G is input to the inverter 4. Although not illustrated, the motor drive device 1 is provided with a voltage detector that detects a voltage value Vd of the direct current supplied from the battery 10, and the voltage value Vd detected by the voltage detector is input to the inverter control device 3 as the battery voltage Vd.

The inverter 4 includes switching elements corresponding to three-phase upper and lower arms, respectively. The inverter 4 controls an on/off state of each switching element based on the gate signal G input from the inverter control device 3. As a result, the direct current power supplied from the battery 10 is converted into three-phase alternating current power and is output to the motor 60.

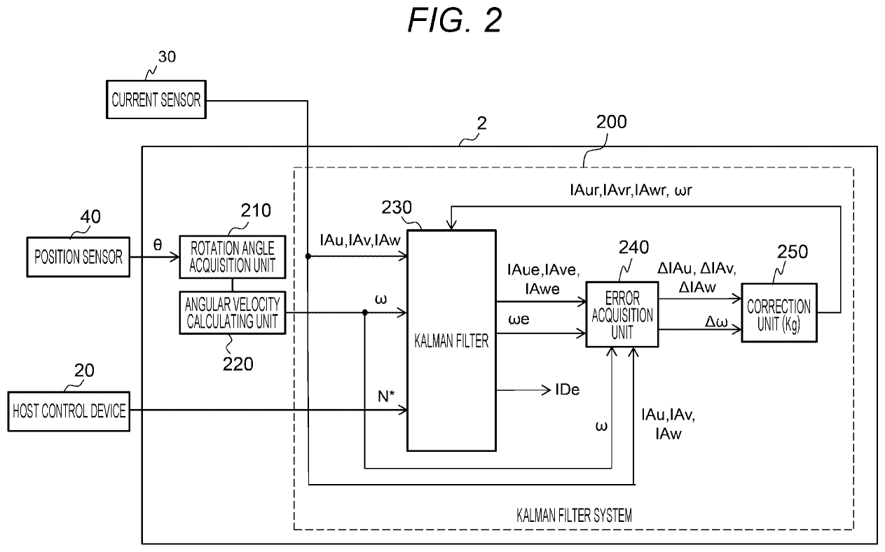

FIG. 2 is a block diagram illustrating a detailed configuration of the direct current estimation device 2. The direct current estimation device 2 includes a Kalman filter system 200, a rotation angle acquisition unit 210, and an angular velocity calculation unit 220. The Kalman filter system 200 includes a Kalman filter 230, an error acquisition unit 240, and a correction unit 250. Error calculation and estimation in the Kalman filter system 200 require error covariance for calculation convenience. In the present embodiment, the system is defined by the following Mathematical expressions (1) to (4), and the value of the error covariance is obtained by performing approximation using sample points and tangents in the system.

$$\begin{matrix}[ Mathematical Expression 1 ] & \\ z ( k ) = [ \begin{matrix}IA ( k ) \\ N ( k ) \\ ω ( k )\end{matrix} ] & ( 1 )\end{matrix}$$

$$\begin{matrix}[ Mathematical Expression 2 ] & \\ y ( k ) = [ \begin{matrix}IA ( k ) \\ ω ( k )\end{matrix} ] & ( 2 )\end{matrix}$$

$$\begin{matrix}[ Mathematical Expression 3 ] & \\ z ( k + 1 ) = f ( z ( k ) , v ( k ) ) & ( 3 )\end{matrix}$$

$$\begin{matrix}[ Mathematical Expression 4 ] & \\ y ( k ) = h ( z ( k ) , w ( k ) ) & ( 4 )\end{matrix}$$

The alternating current observation values IAu, IAv, and IAw acquired by the current sensor 30, the angular velocity observation value ω calculated by the angular velocity calculation unit 50, and the command torque N* are converted into vectors as a state variable z(k) shown in Equation (1). In Equation (1), IA(k) represents the alternating current observation values IAu, IAV, and IAw. An output y(k) is defined by Equation (2). In the Kalman filter 230, the system including the motor drive device 1 and the motor 60 in FIG. 1 is expressed by nonlinear state equations of Equations (3) and (4). Then, next alternating current estimation values IAue, IAve, and IAwe, a next angular velocity estimation value ωe, and a next direct current estimation value IDe can be estimated by the Kalman filter 230 using the state variable z. Note that in Equations (1) to (4), k represents time, v represents system noise associated with a state, and w represents observation noise associated with an output.

As a result, the alternating current estimation values IAue, IAve, and IAwe and the angular velocity estimation value we are output, and values used for calculation at the time of updating the next alternating current estimation values IAue, IAve, and IAwe are calculated. Since the Kalman filter operation is a known technique, a detailed calculation method other than the definition will not be described.

The alternating current observation values IAu, IAv, and IAw detected by the current sensor 30 are input to the Kalman filter 230 and the error acquisition unit 240 of the Kalman filter system 200. The rotation angle acquisition unit 210 acquires the rotation angle observation value θ of the motor 60 from the position sensor 40 and inputs this value to the angular velocity calculation unit 220. The angular velocity calculation unit 220 calculates the angular velocity observation value ω of the motor 60 based on the input rotation angle observation value θ. The calculated angular velocity observation value ω is input to the Kalman filter 230 and the error acquisition unit 240 of the Kalman filter system 200.

The Kalman filter 230 receives the alternating current observation values IAu, IAv, and IAw detected by the current sensor 30, the angular velocity observation value ω calculated by the angular velocity calculation unit 220, the torque command value N* from the host control device 20, and alternating current correction values IAur, IAvr, and IAwr fed back from the correction unit 250. The Kalman filter 230 calculates the alternating current estimation values IAue, IAve, and IAwe, the angular velocity estimation value we, and the direct current estimation value IDe by applying a Kalman filter operation using the alternating current observation values IAu, IAv, and IAw, the angular velocity observation value ω, and the torque command value N* that have been input, the fed-back alternating current correction values IAur, IAvr, and LAwr, and the angular velocity correction value ωr. This Kalman filter operation is repeatedly performed at a predetermined operation cycle, and the direct current estimation value IDe is sequentially updated.

Since the alternating current correction values IAur, IAvr, and IAwr and the angular velocity correction value or that are fed back and input to the Kalman filter 230 are amounts calculated based on the alternating current estimation values IAue, IAve, and IAwe and the angular velocity estimation value we output from the Kalman filter 230 as described later, these values are not input to the Kalman filter 230 at the start of the operation (initial time) of the Kalman filter 230. Therefore, regarding the estimation value output first after the start of the operation, the Kalman filter 230 outputs the alternating current observation values IAu, IAv, and IAw and the angular velocity observation value ω, which have been input, as initial estimation values in accordance with the initial state values of the system, that is, as the alternating current estimation values IAue, IAve, and IAwe and the angular velocity estimation value ωe.

The alternating current estimation values IAue, IAve, and IAwe and the angular velocity estimation value we output from the Kalman filter 230 are input to the error acquisition unit 240. The error acquisition unit 240 calculates a difference between the alternating current estimation values IAue, IAve, and IAwe calculated by the Kalman filter 230 and the alternating current observation values IAu, IAv, and IAw detected by the current sensor 30, and a difference between the angular velocity estimation value we calculated by the Kalman filter 230 and the angular velocity observation value ω calculated by the angular velocity calculation unit 50, thereby acquiring alternating current errors ΔIAu, ΔIAv, and ΔIAw (hereinafter, collectively referred to as ΔIA) and an angular velocity error Δω.

The correction unit 250 calculates a Kalman gain Kg using the error covariance described above. Then, the alternating current error ΔΔIA (ΔIAu, ΔIAv, and ΔIAw) and the angular velocity error Δω calculated by the error acquisition unit 240 are multiplied by the Kalman gain Kg corresponding to the state of the system. Multiplication results Kg·ΔIAu, Kg·ΔIAv, KgΔ·IAw, and Kg·ω are fed back and input to the Kalman filter 230 as alternating current correction values IAur, IAvr, and IAwr and an angular velocity correction value or, respectively.

The Kalman filter 230 performs a well-known nonlinear Kalman filter operation based on the alternating current observation values IAu, IAv, and IAw, the angular velocity observation value ω, and the torque command value N*, which have been input, the alternating current correction values IAur, IAvr, and IAwr and the angular velocity correction value or, which have been fed back and input, and nonlinear state equations (Equations (3) and (4)) corresponding to the system state, thereby calculating the alternating current estimation values IAue, IAve, and IAwe and the angular velocity estimation value we at the next timing (k+1), and the direct current estimation value IDe.

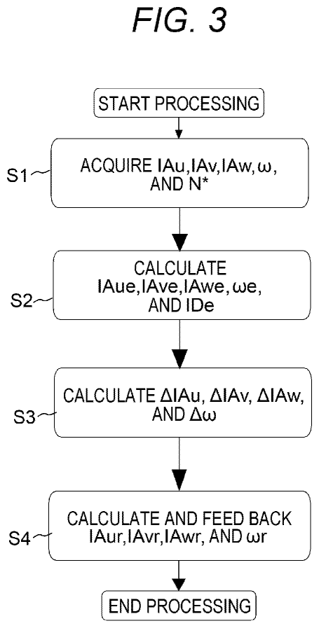

FIG. 3 is an operation flowchart of the Kalman filter system 200. In step S1, the Kalman filter 230 acquires the alternating current observation values IAu, IAv, and IAw from the current sensor 30, the angular velocity observation value w from the position sensor 40, and the torque command value N* from the host control device 20.

In step S2, the Kalman filter 230 performs the Kalman filter operation based on the alternating current observation values IAu, IAv, and IAw, the angular velocity observation value ω, and the torque command value N* respectively acquired in step S1, the fed-back alternating current correction values IAur, IAvr, and IAwr and the angular velocity correction value or, which have been fed back, and calculates the alternating current estimation values IAue, IAve, and IAwe, the angular velocity estimation value we, and the direct current estimation value IDe. However, as described above, regarding the initial estimation value output first after the start of the operation of the Kalman filter 230, the alternating current observation values IAu, IAv, and IAw and the angular velocity observation value ω, which have been input, are output from the Kalman filter 230 as the initial estimation values.

In step S3, the error acquisition unit 240 calculates the alternating current errors ΔIAu, ΔIAv, and ΔIAw, which are the differences between the alternating current estimation values IAue, IAve, and IAwe and the alternating current observation values IAu, IAv, and IAw, and the angular velocity error Δω, which is the difference between the angular velocity estimation value we and the angular velocity observation value ω.

In step S4, the correction unit 250 multiplies each of the calculated alternating current errors ΔIAu, ΔIAv, and ΔIAw and the angular velocity error Δω by the Kalman gain Kg. Then, the alternating current correction values IAur, IAvr, and IAwr and the angular velocity correction value ωr, which are multiplication results, are fed back to the Kalman filter 230, and a series of the processing ends. The processing from step S1 to step S4 illustrated in FIG. 3 is repeatedly executed at predetermined time intervals.

The direct current estimation value IDe is updated every time the series of processing in FIG. 3 is repeatedly executed at a predetermined operation cycle, and the updated direct current estimation value IDe is output from the direct current estimation device 2 to the inverter control device 3. The direct current estimation device 2 with high accuracy can be achieved by sequentially updating the direct current estimation value IDe as described above.

For example, generally-known direct current estimation method using an alternating current and an inverter switching cycle signal has a problem of deterioration in conversion efficiency from direct current to alternating current in a weak field region in which correction is difficult.

On the other hand, in the present embodiment, the Kalman filter 230 is employed in the direct current estimation device 2, and the alternating current observation values IAu, IAv, and IAw and the angular velocity observation value ω are used as input signals to the Kalman filter 230, which is a feature that has not been provided conventionally. In the present embodiment, the estimation accuracy of the direct current estimation device 2 can be improved by fusing the alternating current and the angular velocity information in such a manner that the alternating current errors ΔIAu, ΔIAv, and ΔIAw, which are the differences between the alternating current estimation values and the alternating current observation values, and the angular velocity error Δω, which is the difference between the angular velocity estimation value and the angular velocity observation value, are multiplied by the Kalman gain, the multiplication results are fed back to the Kalman filter 230 as the alternating current correction values IAur, IAvr, and IAwr and the angular velocity correction value or, and the direct current estimation value IDe is sequentially updated.

Note that in the embodiment described above, the Kalman filter 230 performs the Kalman filter operation based on the input torque command value N*, but alternating current command values Iu*, Iv*, and Iw* may be used instead of the torque command value N*. In this case, for example, an arithmetic unit that calculates the alternating current command values Iu*, Iv*, and Iw* from the torque command value N* is disposed in the inverter control device 3, and the alternating current command values Iu*, Iv*, and Iw* are input from the arithmetic unit to the Kalman filter 230.

According to the embodiment of the present invention described above, the following operational effects are obtained.

(C1) As illustrated in FIGS. 1 and 2, in the motor drive device 1 that is a power conversion device that converts a direct current into an alternating current and outputs the alternating current to the motor 60 that is a dynamo-electric machine, the direct current estimation device 2 that estimates a value of the direct current includes the Kalman filter 230 that estimates the direct current estimation value IDe, and uses at least the alternating current observation values IAu, IAv, and IAw and the angular velocity observation value ω of the motor 60 as input signals to the Kalman filter 230.

In the direct current estimation using the Kalman filter 230, the alternating current errors ΔIAu, ΔIAv, and ΔIAw, which are the differences between the alternating current estimation values and the alternating current observation values, and the angular velocity error Δω, which is the difference between the angular velocity estimation value and the angular velocity observation value, are multiplied by the Kalman gain Kg, the multiplication results are fed back to the Kalman filter 230 as the alternating current correction values IAur, IAvr, and IAwr and the angular velocity correction value ωr, and the direct current estimation value IDe is sequentially updated. As described above, in the calculation of the direct current estimation values with the Kalman filter 230, since the estimation is performed by fusing the alternating current and the angular velocity information, the estimation accuracy of the direct current estimation device 2 is improved.

(C2) In (C1), in addition to the alternating current observation values IAu, IAv, and IAw and the angular velocity observation value ω, the torque command value N* or the alternating current command values Iu*, Iv*, and Iw* of the motor 60 may be further used as the input signals to the Kalman filter 230.

(C3) As illustrated in FIG. 1, the motor drive device 1, which is the power conversion device including the direct current estimation device of (C1), includes the inverter control circuit 3 that generates the gate signal G based on the torque command value N* and the direct current estimation value IDe estimated by the direct current estimation device 2, and the inverter 4 that converts a direct current into an alternating current based on the gate signal G. Since the accuracy of the direct current estimation is improved, the performance of the drive control of the motor 60 can be improved.

(C4) As illustrated in FIGS. 2 and 3, in a direct current estimation method in the motor drive device 1 that converts a direct current into an alternating current and outputs the alternating current to the motor 60, at least the alternating current observation values and the angular velocity observation value ω of the motor 60 are input to the Kalman filter 230 as input signals, and the Kalman filter operation is performed based on these input signals to estimate the direct current estimation value IDe.

The embodiment and various modifications described above are merely examples, and the present invention is not limited to these contents as long as the characteristics of the invention are not impaired. Although various embodiments and modifications have been described above, the present invention is not limited to these contents. Other aspects conceivable within the scope of the technical idea of the present invention are also included within the scope of the present invention.

### REFERENCE SIGNS LIST

1 motor drive device
2 direct current estimation device
3 inverter control device
4 inverter
10 battery
30 current sensor
40 position sensor
60 motor
200 Kalman filter system
210 rotation angle acquisition unit
220 angular velocity calculation unit
230 Kalman filter
240 error acquisition unit
250 correction unit

1. A direct current estimation device that estimates a value of a direct current in a power conversion device that converts the direct current into an alternating current and outputs the alternating current to a dynamo-electric machine, the direct current estimation device comprising
a Kalman filter that estimates a direct current estimation value,
wherein the direct current estimation device uses at least an observation value of the alternating current and an angular velocity observation value of the dynamo-electric machine as input signals to the Kalman filter.

2. The direct current estimation device according to claim 1, wherein the direct current estimation device further uses a torque command value or an alternating current command of the dynamo-electric machine as the input signals in addition to the observation value of the alternating current and the angular velocity observation value.

3. A power conversion device comprising the direct current estimation device according to claim 1, the power conversion device comprising:
an inverter control circuit that generates a gate signal based on a torque command value and the direct current estimation value estimated by the direct current estimation device; and
an inverter that converts a direct current into an alternating current based on the gate signal.

4. A direct current estimation method in a power conversion device that converts a direct current into an alternating current and outputs the alternating current to a dynamo-electric machine, the method comprising:
inputting at least an observation value of the alternating current and an angular velocity observation value of the dynamo-electric machine to a Kalman filter as input signals; and
performing a Kalman filter operation based on the input signals to estimate a value of the direct current.
